(19) United States
(12) Patent Application Publication
(10) Pub. No.: US 2017/0309803 A1
(43) Pub. Date: Oct. 26, 2017

(54) Bi-pin LED light bulb and related methods

(71) Applicant: Auroralight, Inc., La Jolla, CA (US)

(72) Inventor: Michael P. Joye, Carlsbad, CA (US)

(21) Appl. No.: 15/497,031

(22) Filed: Apr. 25, 2017

Related U.S. Application Data
(60) Provisional application No. 62/327,366, filed on Apr. 25, 2016.

(51) Int. Cl. H01L 33/64; F21K 9/272; F21K 9/275; F21K 9/232; F21K 9/237; H01J 5/50

(52) U.S. Cl. CPC H01L 33/64; F21K 9/232; F21K 9/237; F21K 9/272; F21K 9/275; H01J 5/50

(57) ABSTRACT

Disclosed are bi-pin LED lamps, like the GY6 lamp, that address the heat-dissipation problems associated with traditional LED light sources.

### CROSS-REFERENCE TO RELATED APPLICATIONS

This application claims the benefit and priority of U.S. Prov. Pat. App. Ser. No. 62/327,366 (filed Apr. 25, 2016) by Auroralight, Inc. for “Outdoor light, improved bi-pin LED light bulb, and related methods.” This provisional document is hereby incorporated by reference in its entirety.

### STATEMENT REGARDING FEDERALLY SPONSORED RESEARCH OR DEVELOPMENT

Not applicable.

### THE NAMES OF THE PARTIES TO A JOINT RESEARCH AGREEMENT

Not applicable.

### REFERENCE TO AN APPENDIX SUBMITED ON A COMPACT DISC AND AN INCORPORATED BY REFERENCE OF THE MATERIAL ON THE COMPACT DISC

Not applicable.

### STATEMENT REGARDING PRIOR DISCLOSURES BY THE INVENTOR OR A JOINT INVENTOR

Reserved for a later date, if necessary.

### BACKGROUND OF THE INVENTION

### Field of Invention

The disclosed subject matter is in the field of bi-pin light-emitting-diode (LED) lighting bulbs.

### Background of the Invention

An LED is a two-lead semiconductor light source. LEDs have become widespread for use in lighting applications because LEDs are favorably smaller in size, lower in power consumption, longer in life, and offer quicker response speeds than alternative incandescent or fluorescent light sources. Although better than alternative light sources, LEDs can be inefficient, wherein 40% to 85% of input power is converted to heat rather than light. This inefficiency can result in heat buildup and, if the heat is not dissipated effectively, a significantly reduced light emitting intensity and service life of the LED light source.

LED lamps or light bulbs are assemblies with an LED light source for use in lighting fixtures and other lighting applications. Bi-pin LED lamps have a light source and two pins. In use, the light source emits light whenever the pins are electrically connected to a power source. Traditional bi-pin LED lamps, like the GY6 lamp, have not adequately addressed the heat-dissipation problems associated with LED light sources.

### SUMMARY OF THE INVENTION

In view of the foregoing, an object of this specification is to disclose bi-pin LED lamps, like the GY6 lamp, that address the heat-dissipation problems associated with traditional LED light sources. In one embodiment, the disclosed subject matter is a GY6 type lamp defined by two copper plates featuring LED light sources and a cylindrical copper base with two pins, where the plates are coupled via a halved joint and press fit into the copper base so that the pins are electrically coupled to the LED light sources, and where the interface of the plates define a heat exchange interface and where the press fit interface of the copper base and the plates defines another heat exchange interface. In use, heat generated during powering of the LED lamps is exchanged across the heat exchange interfaces and ultimately dissipated to the ambient environment through the surfaces of the base.

### BRIEF DESCRIPTION OF THE SEVERAL VIEWS OF THE DRAWINGS

Other objectives of the disclosure will become apparent to those skilled in the art once the invention has been shown and described. The manner in which these objectives and other desirable characteristics can be obtained is explained in the following description and attached figures in which:

FIG. 1 is a perspective view of an improved GY6 LED light bulb;

FIG. 2 is another perspective of the light bulb of FIG. 1;

FIG. 3 is another perspective of the light bulb of FIG. 1;

FIG. 4 is another perspective of the light bulb of FIG. 1;

FIG. 5 is a generic illustration of the light bulb of FIG. 1;

FIG. 6 is an exploded view of the light bulb of FIG. 5;

FIG. 7 is another exploded view of the light bulb of FIG. 5 and illustrates heat exchange interfaces; and,

FIG. 8 is an illustration of heat flow in the light bulb of FIGS. 1 through 7.

In the figures, the following reference numerals refer to these parts:
4000—GY6 light bulb;
4100—copper plate;
4200—copper plate;
4300—LED light sources;
4400—copper base; and,
4500—pins.

It is to be noted, however, that the appended figures illustrate only typical embodiments of this invention and are therefore not to be considered limiting of its scope, for the invention may admit to other equally effective embodiments that will be appreciated by those reasonably skilled in the relevant arts. Also, figures are not necessarily made to scale but are representative.

### DETAILED DESCRIPTION OF PREFFERED EMBODIMENTS

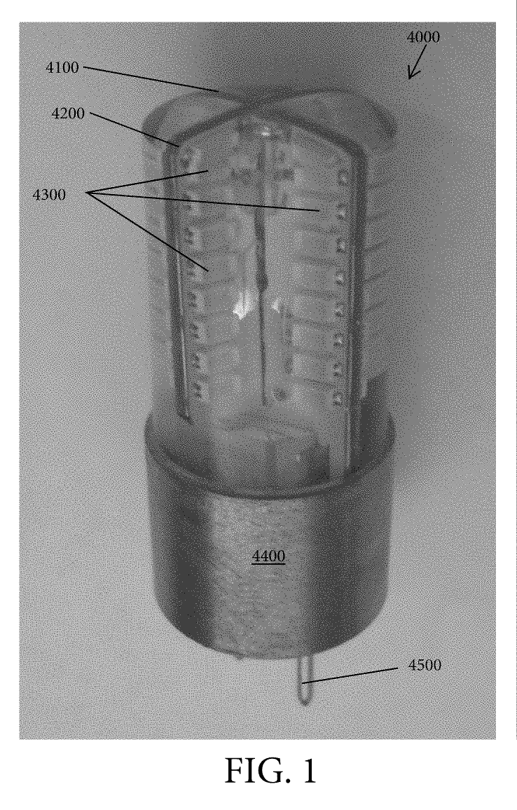

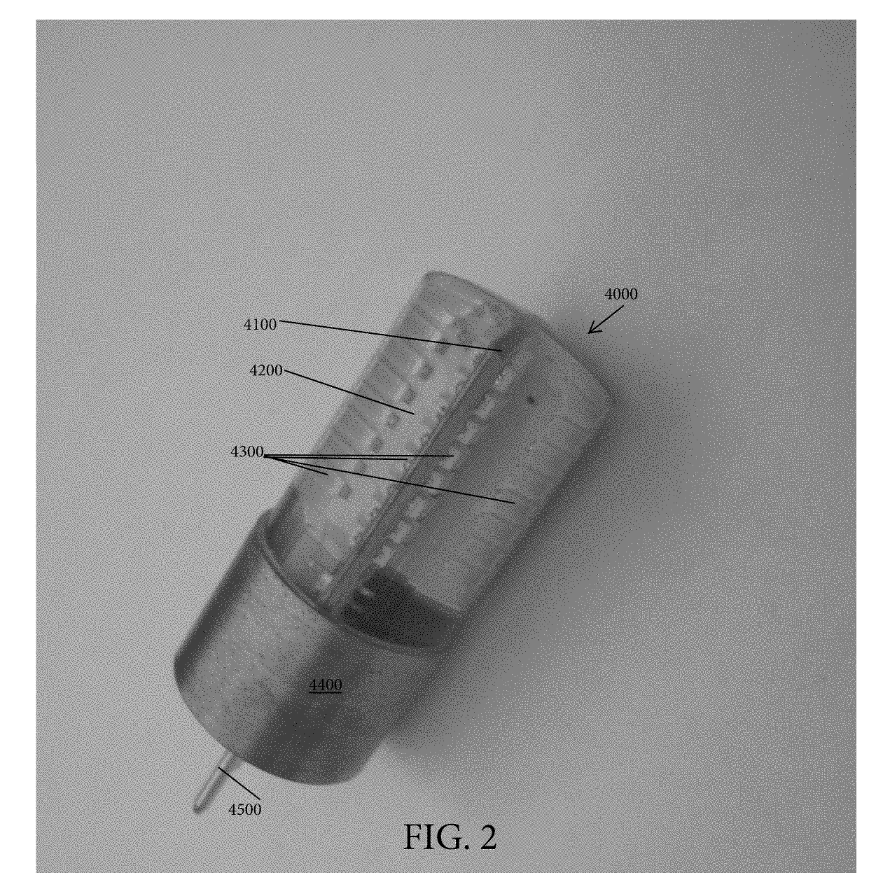

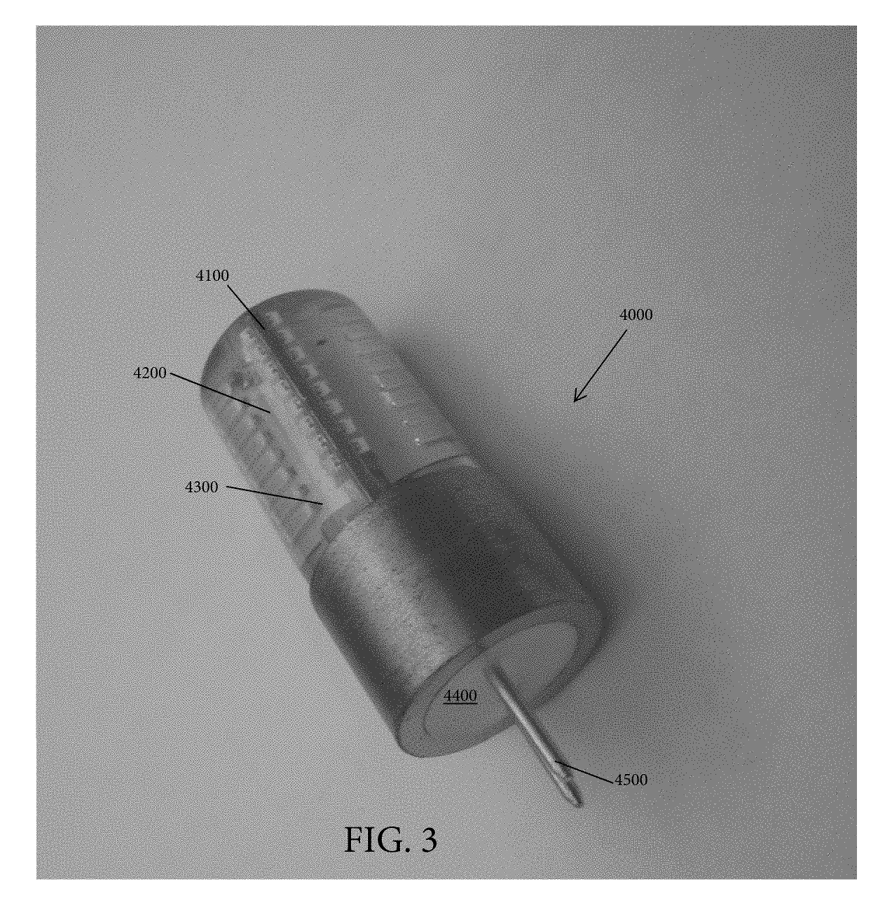

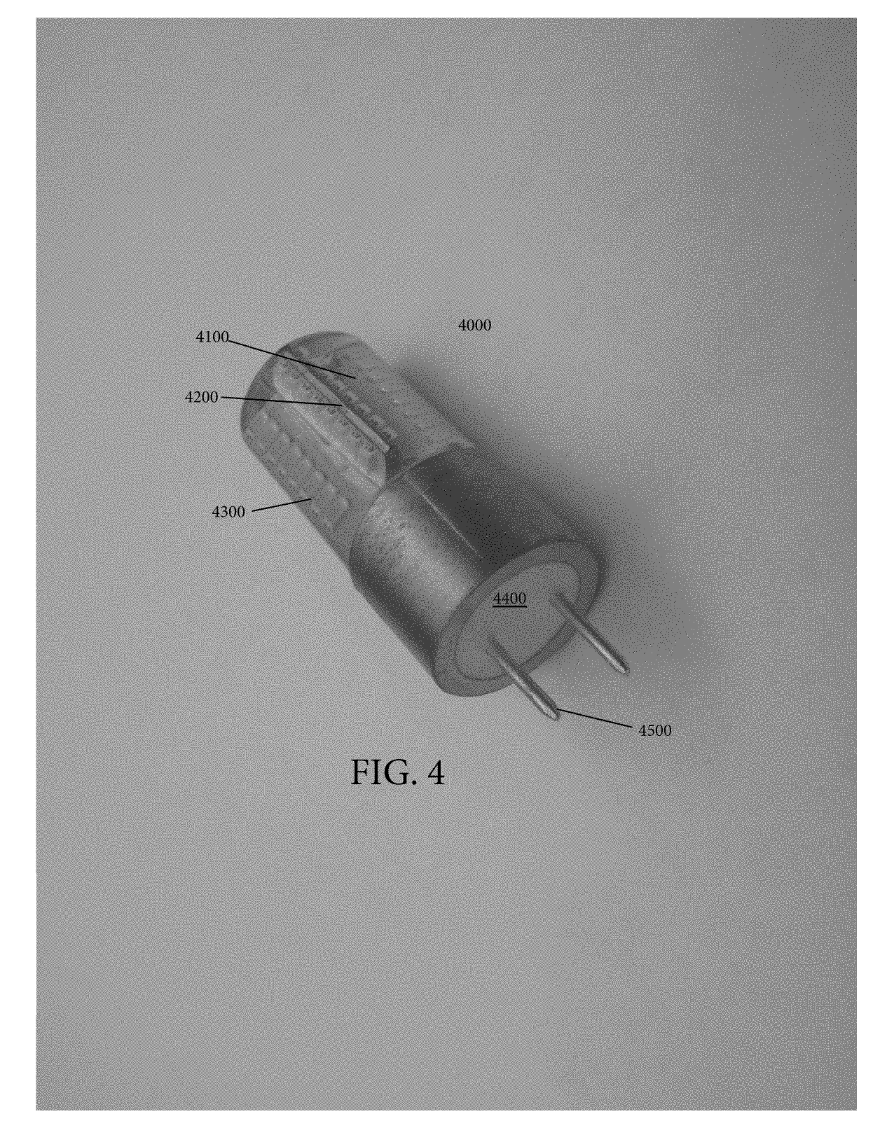

Disclosed by this specification are bi-pin LED lamps, like the GY6 lamp, that addresses the heat-dissipation problems associated with traditional LED light sources. FIGS. 1 through 8 are various perspective views of an improved GY6 LED light bulb 4000. In the depicted embodiment, GY6 type lamp 4000 is defined by two copper plates 4100, 4200 featuring LED light sources 4300 and a cylindrical copper base 4400 with two pins 4500. In the preferred embodiment, the plates 4100, 4200 are coupled via a halved joint and press fit into the copper base 4400 so that the pins 4500 are electrically coupled to the LED light sources 4300. Other electronic components, like LED drivers, can be installed on the plates. As discussed in greater detail below, the interface of the plates may be soldered or press-fit and defines a heat exchange interface. Also discussed in greater detail below, the soldered or press fit interface of the copper base 4400 and the plate 4100 defines another heat exchange interface. In use, heat generated during powering of the LED lamps 4300 is exchanged across the heat exchange interfaces and ultimately dissipated to the ambient environment or other heat sink through the surfaces of the base 4400. The copper plates may also assist in the electric coupling of the pins 4500 to the LED lights 4300.

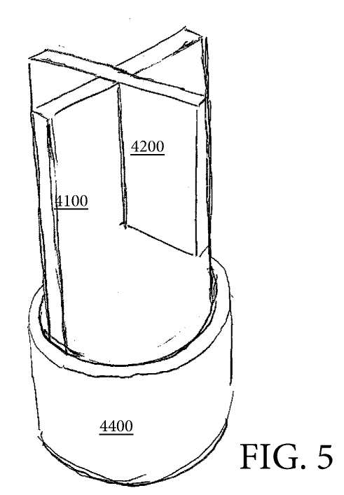

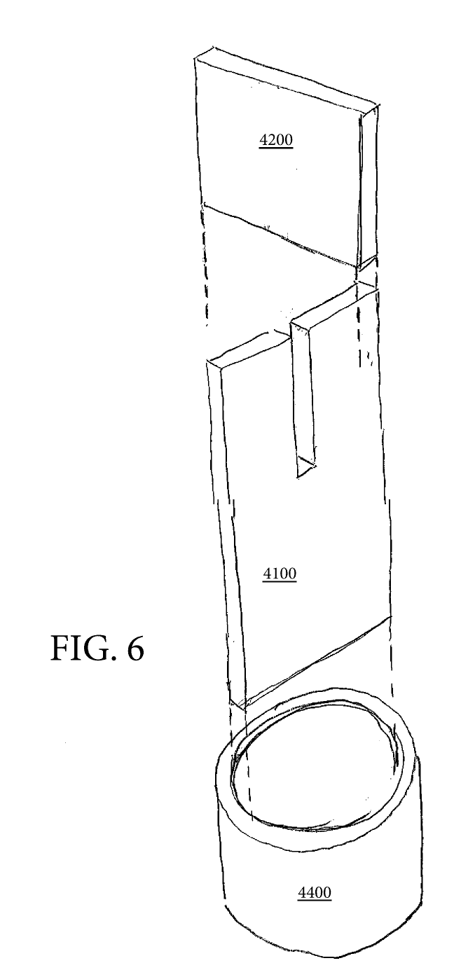

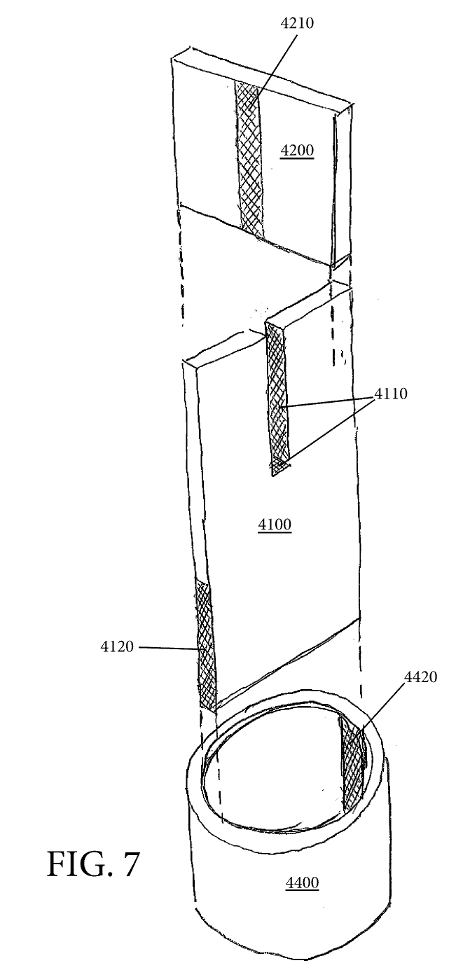

FIG. 5 is a generic illustration of the primary components of the light bulb of FIG. 1. FIG. 6 is an exploded view of the light bulb of FIG. 5. FIG. 7 is another exploded view of the light bulb of FIG. 5 and illustrates heat exchange interfaces. As shown in the figures, the plates 4100, 4200 may be halved jointed together. As shown in FIG. 7, the halved joint creates heat transfer interfaces 4110 and 4210 between the two plates 4100, 4200. Referring back to FIG. 5, the halved jointed plates 4100, 4200 may be press fit or soldered into the cylinder of the base 4400. As shown in FIG. 28, the press fit of the plates 4100, 4200 into the cylinder of the base 4400 creates heat transfer interfaces 4120 and 4420.

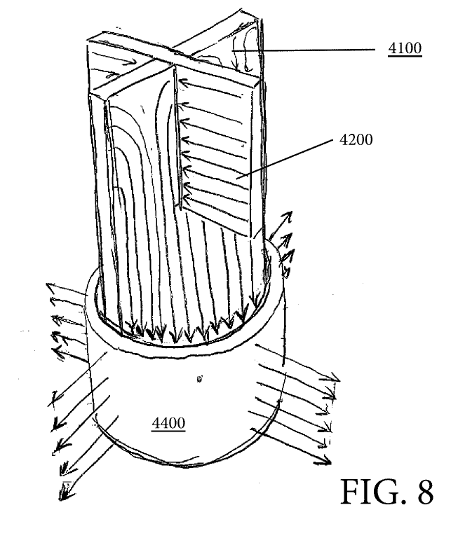

FIG. 8 is an illustration of heat flow in the light bulb of FIGS. 1 through 7. As shown, heat provided to the plates may suitably flow through the heat exchange interfaces and out of the surfaces of the base 4400 to the ambient environment or other heat sink.

Although the method and apparatus is described above in terms of various exemplary embodiments and implementations, it should be understood that the various features, aspects and functionality described in one or more of the individual embodiments are not limited in their applicability to the particular embodiment with which they are described, but instead might be applied, alone or in various combinations, to one or more of the other embodiments of the disclosed method and apparatus, whether or not such embodiments are described and whether or not such features are presented as being a part of a described embodiment. Thus the breadth and scope of the claimed invention should not be limited by any of the above-described embodiments.

Terms and phrases used in this document, and variations thereof, unless otherwise expressly stated, should be construed as open-ended as opposed to limiting. As examples of the foregoing: the term “including” should be read as meaning “including, without limitation” or the like, the term “example” is used to provide exemplary instances of the item in discussion, not an exhaustive or limiting list thereof, the terms “a” or “an” should be read as meaning “at least one,” “one or more,” or the like, and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that might be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases might be absent. The use of the term “assembly” does not imply that the components or functionality described or claimed as part of the module are all configured in a common package. Indeed, any or all of the various components of a module, whether control logic or other components, might be combined in a single package or separately maintained and might further be distributed across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives might be implemented without confinement to the illustrated examples. For example, block diagrams and their accompanying description should not be construed as mandating a particular architecture or configuration.

All original claims submitted with this specification are incorporated by reference in their entirety as if fully set forth herein.

I claim:

1. A bi-pin LED lamp that addresses the heat-dissipation problems associated with traditional LED light sources.

2. The bi-pin LED lamp of claim 1 further comprising:
at least one copper plate featuring LED light sources and a cylindrical copper base with two pins;
where said at least one plate is press-fit into the copper base so that the pins are electrically coupled to the LED light sources; and,
where the press-fit interface of the copper base and the at least one plate defines a heat exchange interface.

3. The bi-pin LED lamp of claim 2 further wherein said at least one plate is two plates and wherein the plates are coupled via a halved joint defined by an interface and where the halved joint interface of the plates define a heat exchange interface.

4. The bi-pin LED lamp of claim 3 wherein heat generated during powering of the LED lamps is exchanged across the heat exchange interfaces and ultimately dissipated to the ambient environment through the surfaces of the base.
